(19) United States
(12) Patent Application Publication
(10) Pub. No.: US 2009/0246941 A1
(43) Pub. Date: Oct. 1, 2009

(54) DEPOSITION APPARATUS, DEPOSITION SYSTEM AND DEPOSITION METHOD

(75) Inventors: Shinji Matsubayashi, Hyogo (JP); Kazuki Moyama, Hyogo (JP); Yasuhiro Tobe, Tokyo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/376,459

(22) PCT Filed: Aug. 8, 2007
(86) PCT No.: PCT/JP2007/065514

§ 371 Date: Feb. 5, 2009

(30) Foreign Application Priority Data
Aug. 9, 2006 (JP) 2006-216787

(51) Int. Cl. H01L 21/203; C23C 14/34

(52) U.S. Cl. 438/478; 204/298.26; 257/E21.091

(57) ABSTRACT

A deposition system is provided to avoid cross contamination in each layer formed in a manufacturing process of organic electroluminescent device, etc., and also provided to reduce footprint. Provided is an apparatus 13 for forming a film onto a substrate which includes a first deposition mechanism 35 for forming a first layer and a second deposition mechanism 36 for forming a second layer in a processing chamber 30. The apparatus 13 further includes an exhaust opening 31 through which inside of the processing chamber 30 is evacuated, and the first deposition mechanism 35 is positioned closer to the exhaust opening 31 than the second deposition mechanism 36. The first layer, for example, is formed on the substrate by an evaporation method by the first deposition mechanism 35 and the second layer, for example, is formed on the substrate by a sputtering method by the second deposition mechanism 36.

### TECHNICAL FIELD

The present invention relates to a deposition apparatus and a deposition system for forming a layer of a predetermined material on a substrate, and also relates to a deposition method.

### BACKGROUND ART

In recent years, an organic electroluminescent (OEL) device has been developed utilizing electroluminescence (EL). As the organic electroluminescent (OEL) device generates almost no heat, it consumes lower power compared with a cathode-ray tube. Further, since the OEL device is a self-luminescent device, there are some other advantages, for example, a view angle wider than that of Liquid Crystal Display (LCD), so that progress thereof in the future is expected.

Most typical structure of Organic Electroluminescent device includes an anode (positive electrode) layer, a light-emitting layer and a cathode (negative electrode) layer stacked sequentially on a glass substrate to form a sandwiched shape. So as to bring out light from the light-emitting layer, a transparent electrode made of Indium Tin Oxide (ITO) is used as the anode layer on the glass substrate. As to the Organic Electroluminescent device of this type, generally OEL device is manufactured by forming the light-emitting layer and the cathode layer in this order on a preformed ITO layer (anode layer) on the glass substrate.

In addition, in order to ease the electron movement from the cathode layer to the light emitting layer, there is formed a work function adjustment layer (electron transport layer) therebetween. This work function adjustment layer is formed by, for example, depositing alkali metal, such as Lithium on an interface of the light emitting layer in the cathode layer side by evaporation. A deposition apparatus shown in Patent Document Number 1, for example, is known as a fabricating apparatus for the above described Organic Electroluminescent device.

### Patent Document 1: Japanese Patent Laid-open Publication No. 2004-79904

### DISCLOSURE OF THE INVENTION

### Problems to be Solved by the Invention

In an Organic Electroluminescent device manufacturing process, although a film forming process such as an evaporation method or a Chemical Vapor Deposition process is performed to form each layer, cross-contamination arising from each layer formation process should be somehow avoided. For example, there is one possible way that the deposition apparatus for forming the work function adjustment layer by a vapor deposition is provided in the same chamber in which a deposition mechanism for the light emitting layer is disposed so that the light emitting layer and the work function adjustment layer may be successively deposited. If, however, alkali metal as a material for the work function adjustment layer is immixed into the light emitting layer inadvertently, the light emitting efficiency gets lowered drastically.

On the other hand, to avoid this undesirable intermix, deposition apparatuses for each layer of the organic EL device are disposed in different processing chambers. But, the deposition system size becomes larger and the footprint of whole deposition system is increased if an independent processing chamber is adopted for every deposition mechanism. Further, the substrate to be processed is transferred from the processing chamber to the subsequent processing chamber every time the process is completed, thus resulting in an increase of carry in/out steps. Therefore, throughput can be limited.

The object of the present invention is to avoid cross-contamination in each layer arising from the each film forming process, further to provide deposition system with reduced footprint and higher productivity.

### Means for Solving the Problems

According to the present invention, a deposition apparatus is provided for forming a film on a substrate to be processed, which includes, in a processing chamber, a first deposition mechanism for forming a first layer and a second deposition mechanism for forming a second layer.

In this deposition apparatus, an exhaust port is provided to evacuate inside of the processing chamber and the first deposition mechanism may be positioned closer to the exhaust port than the second deposition mechanism. In this case, the first deposition mechanism may be disposed between the exhaust port and the second deposition mechanism. Moreover, a transfer opening for loading or unloading the substrate to be processed into or from the processing chamber is provided, and the first deposition mechanism and the second deposition mechanism may be disposed between the exhaust port and the transfer opening. Furthermore, an alignment mechanism to align a mask to a corresponding position of the substrate may be adopted between the second deposition mechanism and the transfer opening. In addition, in the processing chamber, a substrate transfer mechanism for transferring the substrate to each processing position of the first deposition mechanism, the second deposition mechanism and the alignment mechanism may be provided. The first deposition mechanism is a film forming mechanism to form a first layer, for example, onto the substrate by an evaporation method and the second deposition mechanism is a film forming mechanism to form a second layer, for example, by a sputtering method onto the substrate.

According to the present invention, a deposition system for forming a film on a substrate is provided, which includes a deposition apparatus having a third deposition mechanism for forming a third layer in a processing chamber and the first deposition mechanism and the second deposition mechanism provided inside of the processing chamber.

In this deposition system, a transfer mechanism may be provided which transfers the substrate between the deposition apparatus having the third deposition mechanism and the deposition apparatus having the first deposition mechanism. Also, the third deposition mechanism is used for forming the third layer by an evaporation method, for example.

According to the present invention, a deposition method is provided to form a film on a substrate to be processed, which includes forming a first film by a first deposition mechanism and subsequently, forming a second film by a second deposition mechanism.

In this film forming method, the exhaust operation of the interior of the processing chamber may be performed at a position closer to the first deposition mechanism than to the second deposition mechanism. Further, for example, a first layer may be deposited on the substrate by an evaporating method by the first deposition mechanism, and a second layer may be formed on the substrate by a sputtering method by the second deposition mechanism, for example.

Further, according to the present invention, a film forming method for depositing on a substrate to be processed is provided, which includes forming a third layer by a third deposition mechanism in a processing chamber, and subsequently, forming a first layer by a first deposition mechanism and then forming a second layer by a second deposition mechanism in a different processing chamber.

In this deposition method, inside of the processing chamber may be evacuated at a point closer to the first deposition mechanism than to the second deposition mechanism. Moreover, the third layer is formed on the substrate by, for example, an evaporating deposition method by the third deposition mechanism, the first layer is formed on the substrate by, for example, an evaporating method in the first deposition mechanism and the second layer is formed on the substrate by a sputtering deposition method in the second deposition mechanism, for example.

### EFFECT OF THE INVENTION

According to the present invention, since the first deposition mechanism and the second deposition mechanism are provided in the same processing chamber, deposition apparatus and deposition system can be small in size. Likewise, throughput can be increased because the first layer and the second layer are successively formed in single processing chamber.

Further, according to the present invention, as the first deposition mechanism is provided in a shorter distance to the exhaust port than the distance from the second deposition mechanism to the exhaust port, the material used for the first deposition mechanism is prevented from flowing to the second deposition mechanism side, and thus the contamination to the second layer is avoided.

Moreover, the third deposition mechanism is disposed in a processing chamber and the first and second deposition mechanisms are disposed in a different processing chamber, so that the contamination to the third layer and the contamination to the first and second layers can be avoided.

### BRIEF DESCRIPTION OF THE DRAWINGS

FIG. 1 is a flow chart of an organic electroluminescent device fabrication process;

FIG. 2 is a plain view of a deposition system in accordance with an embodiment of the present invention;

FIG. 3 is an overview structure of a sputtering-evaporating apparatus;

FIG. 4 is a substrate transfer stage inside of the sputtering-evaporating apparatus;

FIG. 5 is a top view of an evaporating apparatus (first deposition mechanism);

FIG. 6 is a cross-sectional view taken along line (X-X) of FIG. 5;

FIG. 7 is an overview structure of a sputtering apparatus (mechanism);

FIG. 8 is an overview structure of an evaporating apparatus (mechanism); and

FIG. 9 is an overview structure of an evaporating apparatus (third deposition mechanism).

### EXPLANATION OF CODES

A organic EL device
G substrate
M mask
1 anode layer
2 light emitting layer (third layer)
3 work function adjustment layer (first layer)
4 cathode layer (second layer)
10 deposition system
11 transfer apparatus
12 substrate load lock apparatus
13 sputtering-evaporating apparatus
14 alignment apparatus
15 shape forming apparatus
16 mask load lock apparatus
17 CVD apparatus
18 substrate reverse apparatus
19 evaporating apparatus
30 processing chamber
31 exhaust port
33 transfer opening
35 evaporating mechanism (first deposition mechanism)
36 sputtering mechanism (second deposition mechanism)
37 alignment mechanism
40 transfer mechanism
70 processing chamber
85 evaporating mechanism (third deposition mechanism)

### BEST MODE FOR CARRYING OUT THE INVENTION

Below, embodiments of the present invention will be explained referring to the drawings. In the following embodiment, as an example of deposition, a manufacturing process for an organic electroluminescent device A which is manufactured by forming an anode (positive electrode) layer 1, a light emitting layer 2 and a cathode (negative electrode) layer 4 on a glass substrate G is described in detail. In the specification and the drawings, like reference numerals denote like parts having substantially identical functions and configurations, so that redundant description thereof may be omitted.

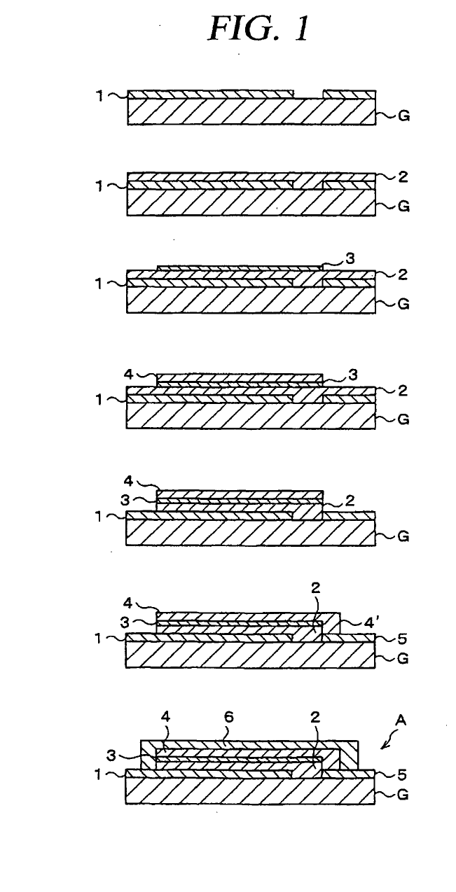

From FIGS. 1 (1) through (7), there is described the manufacturing process of the organic electroluminescent device A. As shown in FIG. 1 (1), on a surface of the glass substrate G used for this embodiment, the anode (positive electrode) layer 1 is preformed as a predetermined pattern. A transparent electrode is used for the anode layer 1 made of, for example, ITO (Indium Tin Oxide).

First of all, as described in FIG. 1 (2), the light emitting layer 2 is formed on the anode layer 1 over the glass substrate G. This light emitting layer 2 is formed by depositing, for example, aluminato-tris-8-hydroxyquinolate (Alq3) on the surface of the glass substrate G. Before forming the light emitting layer 2, a hole transfer layer (HTL) (not shown in the figure), including, e.g., NPB (N,N-di(naphthalene-1-yl)-N,N-diphenyl-benzidene) is deposited on the anode layer 1 by evaporation, and then the light emitting layer 2 is formed on it to form a multiple stacked structure.

In the next step, as shown in FIG. 1 (3), on an interface of the light emitting layer 2, a work function adjustment layer 3 is deposited to form a predetermined shape by evaporating alkali metal such as Li. The work function adjustment layer 3 acts as an ETL (Electron Transport Layer) to ease electron transport from the cathode layer 4 (explained later) to the light emitting layer 2. Aforementioned work function adjustment layer 3 is deposited by evaporation with, e.g., alkali metal such as Li by using a pattern mask.

Subsequently, as shown in FIG. 1 (4), the cathode (negative electrode) layer 4 is patterned onto the work function adjustment layer 3. This cathode layer 4 is formed by sputtering, for example, Ag, Mg/Ag alloy using a pattern mask.

Next, as shown in FIG. 1 (5), the light emitting layer 2 is formed into a predetermined shape corresponding to that of the cathode layer 4.

Further, as shown in FIG. 1 (6), a connecting portion 4′ of the cathode layer 4 is formed so as to electrically connect it to an electrode 5. This connecting portion 4′ is formed by sputtering, for example, Ag, Mg/Ag alloy using a pattern mask.

Finally, as described in FIG. 1 (7), a sealing film 6 including, for example, a nitride film is formed by a CVD to encapsulate a whole sandwiched-structure having the light emitting layer 2 interleaved between the cathode layer 4 and the anode layer 1, and then the organic electroluminescent device A is manufactured.

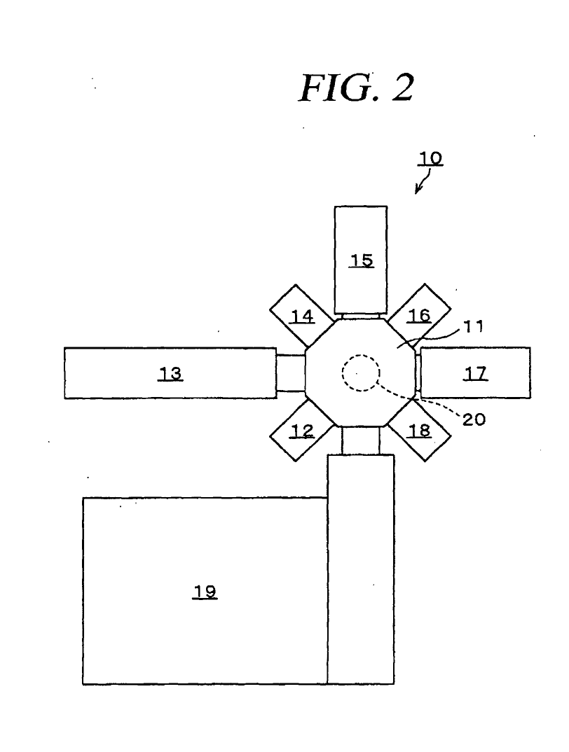

FIG. 2 shows a drawing to explain a deposition system 10 in accordance with an embodiment of the present invention. This deposition system 10 is configured to manufacture the organic electroluminescent device A as described in FIG. 1. Here, in manufacturing the device, the work function adjustment layer 3, the cathode layer 4, and the light emitting layer 2 (including, for example, the hole transport layer) are explained in detail as a first layer, a second layer, and a third layer, respectively.

In the deposition system 10, a substrate load lock apparatus 12, a sputtering-evaporating apparatus 13, an alignment apparatus 14, a shape forming apparatus 15 for the light emitting layer 2, a mask load lock apparatus 16, a CVD apparatus 17, a substrate reverse apparatus 18, and an evaporating apparatus 19 are arranged around a transfer apparatus 11. In the present invention, the sputtering-evaporating apparatus 13 is a deposition apparatus for forming the work function adjustment layer 3 as the first layer and the cathode layer 4 as the second layer. The evaporating apparatus 19 corresponds to a deposition apparatus for forming the light emitting layer 2 as the third layer.

The transfer apparatus 11 includes a transfer mechanism 20 which transfers a substrate G into/out of the apparatuses 12 through 19 independently. Therefore, the transfer apparatus 11 can transfer the substrate G among the apparatuses 12 through 19 in an arbitrary order.

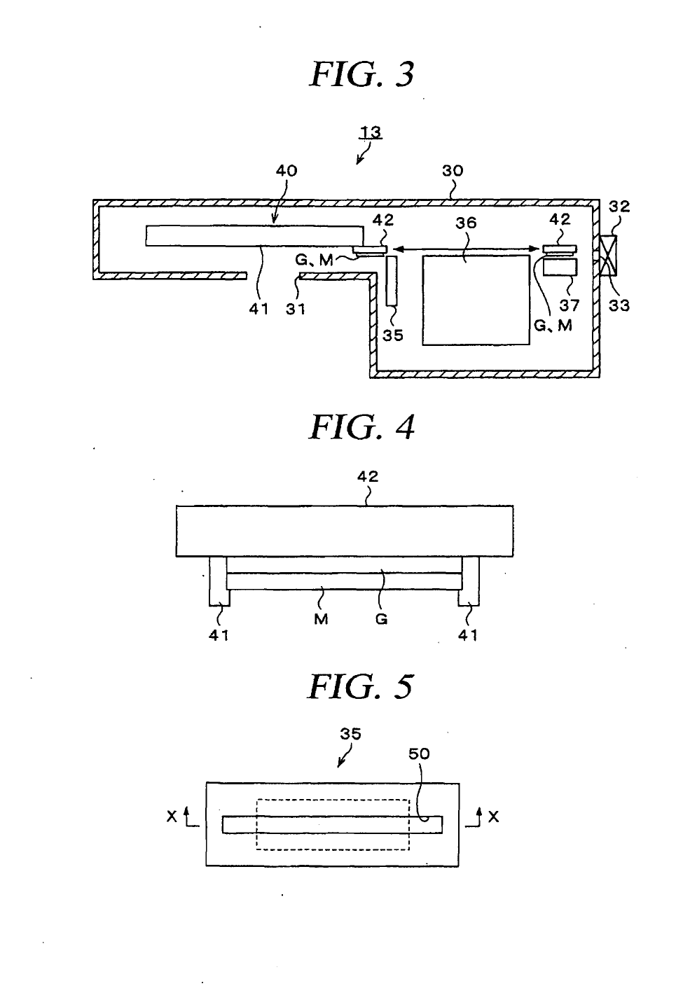

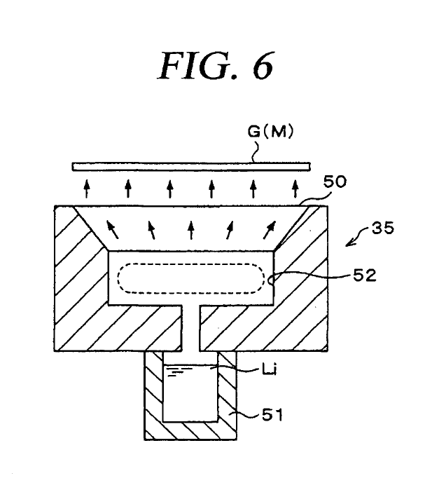

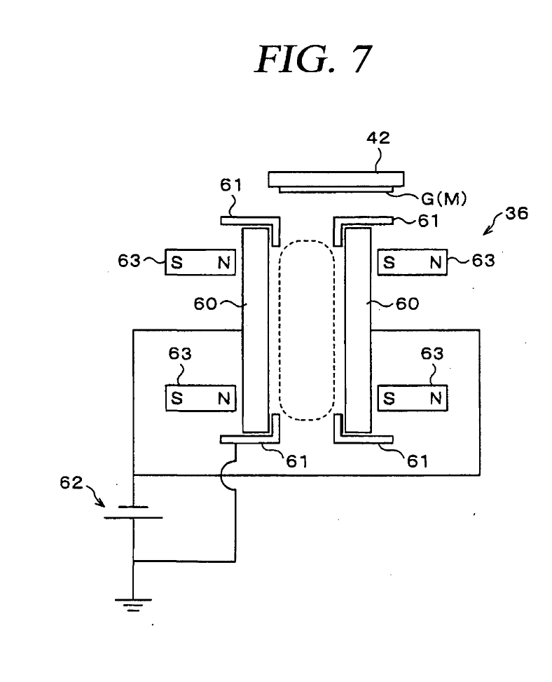

FIG. 3 schematically shows an overview drawing of the sputtering-evaporating apparatus 13 for forming the first and the second layers. FIG. 4 shows a side view of a stage 42 which enables the substrate G to be transferred in the sputtering-evaporating apparatus 13. FIG. 5 and FIG. 6 show a top view of an evaporating mechanism 35 (FIG. 5) and a cross sectional view taken along line X-X in FIG. 5. FIG. 7 shows a schematic drawing of a sputtering mechanism 36 disposed in the sputtering-evaporating apparatus 13. In the present invention, the evaporating mechanism 35 in the sputtering-evaporating apparatus 13 corresponds to a first deposition apparatus for forming the work function adjustment layer 3 as the first layer. Further, the sputtering mechanism 36 corresponds to a second deposition apparatus for forming the cathode layer 4 as the second layer.

As shown in FIG. 3, at the bottom surface of a processing chamber 30 which constitutes the sputtering-evaporating apparatus 13, there is an exhaust opening 31 through which inside of the processing chamber 30 is evacuated to a reduced pressure by using a non-illustrated vacuum unit. At the side of the processing chamber 30, there is a transfer opening 33 opened or closed by a gate valve 32. Through the transfer opening 33, the substrate G is transferred into or out of the sputtering-evaporating apparatus 13 by the above-mentioned transfer mechanism 20 of the transfer apparatus 11.

Inside of the processing chamber 30, the evaporating mechanism 35 as the first deposition mechanism, the sputtering mechanism 36 as the second deposition mechanism, and an alignment mechanism 37 for aligning a mask M corresponding to the substrate G are disposed in sequence between the exhaust port 31 and the transfer opening 33. In the present embodiment, between the exhaust port 31 and the transfer opening 33, the evaporating mechanism 35, the sputtering mechanism 36 and the alignment mechanism 37 are arranged in a straight-line shape. In this configuration, the evaporating mechanism 35 is disposed closer to the exhaust port 31 and the evaporating mechanism 35 is positioned between the sputtering mechanism 36 and the exhaust port 31. The alignment mechanism 37 is positioned between the sputtering mechanism 36 and the transfer opening 33. For one example, the distance from the center of the evaporating mechanism 35 to the exhaust port 31 can be 800 to 900 mm (832 mm for instance) and the distance from the center of the sputtering mechanism 36 to the exhaust port 31 can be 1400 to 1500 mm (1422 mm for instance).

Basically, the sputtering process performed in the sputtering mechanism 36 has directionality and a target 60's material is supplied to the surface of the substrate G. In contrast, vapor for the work function adjustment layer 3 generated in the evaporating mechanism 35 has isotropic feature so that the vapor spreads in all directions like a point light source. So, in this present embodiment, to dispose the evaporating mechanism 35 closer to the exhaust port 31 prevents the vapor for the work function adjustment layer 3 generated from the evaporating mechanism 35 from affecting the process performed in the sputtering mechanism 36.

In addition, in the processing chamber 30, there is a transfer mechanism 40 for transferring the substrate G to each processing position of the evaporating mechanism 35, the sputtering mechanism 36 and the alignment mechanism 37. As illustrated in FIG. 4, the transfer mechanism 40 includes the stage 42, on the lower surface of which the substrate G and the mask M are held by a chuck 41 and an expansion and contraction mechanism 43 to move the stage 42 to the position above the evaporating mechanism 35, the sputtering mechanism 36 and the alignment mechanism 37. The expansion and contraction mechanism 43 is covered in whole by a bellows to prevent particles from coming into the processing chamber 30.

The substrate G and the mask M are transferred into the processing chamber 30 and to the alignment mechanism 37 through the transfer opening 33 by aforementioned transfer mechanism 20 of the transfer apparatus 11. Then the substrate G and the mask M handed to the alignment mechanism 37 are held to be aligned onto the bottom surface of the stage 42.

In the first place, the transfer mechanism 40 transfers the substrate G and the mask M held on the bottom surface of the stage 42 to the position above the evaporating mechanism 35. Then, the work function adjustment layer 3 (first layer) is deposited by evaporation on the surface of the substrate G to form a predetermined pattern by the evaporating mechanism 35. Next, the substrate G and the mask M held on the bottom surface of the stage 42 are transferred to the point above the sputtering mechanism 36. Then, the cathode layer 4 (second layer) is deposited by sputtering on the surface of the substrate G to form a predetermined pattern by the sputtering mechanism 36. After that, the substrate G and the mask M are transferred to the alignment mechanism 37. Finally, the above-mentioned transfer mechanism 20 of the transfer apparatus 11 transfers the substrate G and the mask M which have been transferred to the alignment mechanism 37 out of the processing chamber 30 through the transfer opening 33.

As shown in FIG. 5, on the upper surface of the evaporating mechanism 35 corresponding to the first deposition mechanism, a slit 50 is formed to make a right angle with the transfer direction (stage 42's moving direction) of the substrate G. The length of the slit 50 is almost the same as the width of the substrate G being transferred over the evaporating mechanism 35.

A heat controllable container 51 containing the material for the work function adjustment layer 3 (as the first layer), for example, alkali metal such as lithium, is equipped at the bottom of the evaporating mechanism 35. Vapor of the alkali metal heated and melted in the heat controllable container 51 is supplied upward from the slit 50 via a buffer chamber 52. Then, the alkali metal is deposited on the surface of the substrate G passing through upper side of the evaporating mechanism 35 so that the work function adjustment layer 3 is formed.

As shown in FIG. 7, the sputtering mechanism 36 as the second deposition mechanism is a facing target sputter (FTS) where a pair of plate-shaped targets 60 is disposed to face each other at a predetermined distance. Each target 60 is Ag or Mg/Ag alloy, for example. Ground electrodes 61 are disposed at upper and lower sides of each target 60, and voltage is applied between each target 60 and the ground electrodes 61 from a power source 62. Further, outside of each target 60, a magnet 63 is disposed to generate magnetic field between the targets 60. While generating the magnetic field between the targets 60, glow discharge is generated between each target 60 and the ground electrodes 61, and plasma is generated between the targets 60. By utilizing a sputtering phenomenon using this plasma, material of the target 60 is sputtered to be deposited onto the surface of the substrate G passing above the sputtering mechanism 36 to form the cathode layer 4.

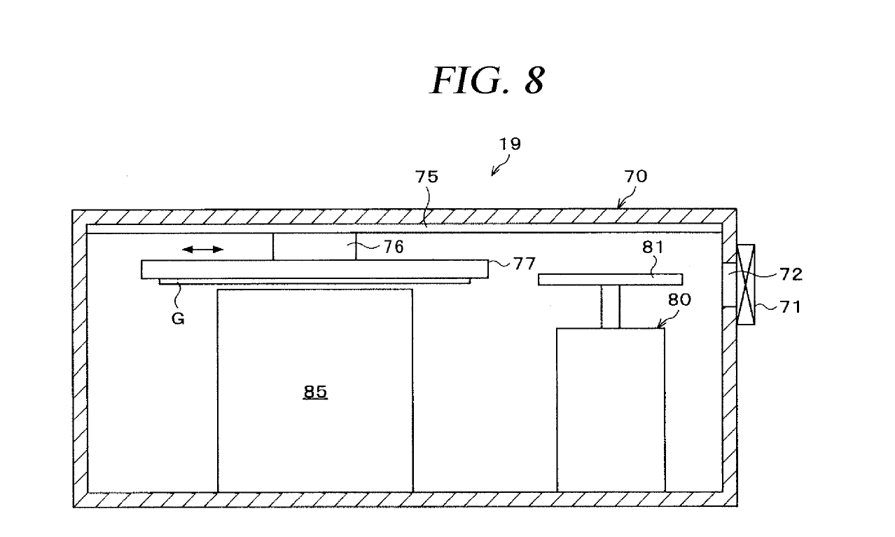

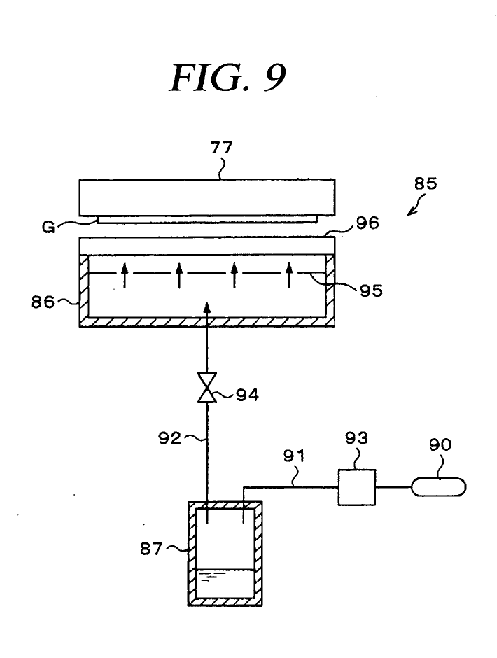

FIG. 8 shows a schematic view of the structure for the evaporating apparatus 19 as the deposition apparatus for forming the third layer. FIG. 9 shows a schematic drawing of the evaporating mechanism 85 disposed in the evaporating apparatus 19. In the present invention, the evaporating mechanism 85 disposed in the evaporating apparatus 19 corresponds to a third deposition mechanism for forming the light emitting layer 2 as the third layer (including the hole transport layer, etc.).

At the side of a processing chamber 70 constituting the evaporating apparatus 19, equipped is a transfer opening 72 opened and closed by a gate valve 71, through which the substrate G is transferred to the evaporating apparatus 19 by aforementioned transfer mechanism 20 in the transfer apparatus 11.

At the top portion of the processing chamber 70, there are provided a guide member 75 and a holding member 76 which moves along the guide member 75 by a suitable actuator (not shown). On the holding member 76, a substrate holding member 77 such as an electricstatic chuck is provided and the substrate G is held on the lower surface of the substrate holding member 77 horizontally.

In addition, provided is an alignment mechanism 80 between the transfer opening 72 and the substrate holding member 77. The alignment mechanism 80 has a stage 81 for aligning the substrate, and the substrate G transferred into the processing chamber 70 through the transfer opening 72 is at first held on the stage 81. After the alignment is completed, the stage 81 moves upward, and the substrate G is transferred to the substrate holding member 77.

Inside of the processing chamber 70, the evaporating mechanism 85 as the third deposition mechanism is disposed at the opposite side of the transfer opening 72 and the alignment mechanism 80 is disposed therebetween. As shown in FIG. 9, the evaporating mechanism 85 includes a deposition unit 86 underneath the substrate G held on the substrate holding member 77 and an evaporating unit 87 which accommodates the evaporating material for the light emitting layer 2. The evaporating unit 87 has a heater (not shown), and vapor of the evaporating material for the light emitting layer 2 is generated in the evaporating unit 87 by heat generated with the heater.

Connected to the evaporating unit 87 are a carrier gas introducing line 91 for introducing a carrier gas from a supply source 90 and a supply line 92 for supplying the vapor of the evaporating material for the light emitting layer 2 generated in the evaporating unit 87 together with the carrier gas to the deposition unit 86. There is provided a flow valve 93 to control the amount of the carrier gas flowing into the evaporating unit 87 on the carrier gas introducing line 91. A normal open valve 94 is provided on the supply line 92, which may be closed when, for example, replenishing the evaporating material of the light emitting layer 2 in the evaporating unit 87.

Inside of the deposition unit 86, a diffusion member 95 is provided to diffuse the vapor of the evaporating material for the light emitting layer 2 transported from the evaporating unit 87. Furthermore, on upper side of the deposition unit 86, a filter 96 is provided to face the lower surface of the substrate G.

In addition, the substrate load lock apparatus 12 depicted in FIG. 2 is used for transferring the substrate G into/out of the deposition system 10, in a state where the interior atmosphere of the deposition system 10 is separated from the outside. The alignment apparatus 14 aligns the substrate G or the substrate G and mask M, and is provided for the apparatus, for example, the CVD apparatus 17 having no alignment mechanism. The shape forming apparatus 15 is used for forming the light emitting layer 2 formed on the substrate G into a desired shape. In the mask load lock apparatus 16, a mask is transferred into/out of the deposition system 10 in a state where the interior atmosphere of the deposition system 10 is separated from the outside. The CVD apparatus 17 is utilized for forming the sealing film 6 made of a nitride film or the like by the CVD to encapsulate the organic luminescent device A. The substrate reverse apparatus 18 appropriately reverses the substrate G to change the surface orientation, so that the surface (target surface) of the substrate G is oriented along the opposite direction of a gravitational force or is oriented along the direction of the gravitational force. In the present embodiment, the film formation is carried out while the substrate G's surface is facing downward in the sputtering-evaporating apparatus 13 and the evaporating apparatus 19, and the processes are performed while the substrate G's surface faces upward in the shape forming apparatus 15 and the CVD apparatus 17. Therefore, the transfer apparatus 11 transfers the substrate G into the substrate reverse apparatus 18 and changes the surface orientation if necessary, while transferring it among apparatuses.

Now, in the deposition system 10 configured as above, the substrate G transferred via the substrate load lock apparatus 12 is at first transferred into the evaporating apparatus 19 by the transfer mechanism 20 in the transfer apparatus 11. In this case, as explained in FIG. 1 (1), the anode layer 1 made of, for example, the ITO is preformed as a predetermined pattern on the surface of the substrate G.

In the evaporating apparatus 19, after aligning the substrate G in the alignment mechanism 80, it is held on the substrate holding member 77 while the substrate G's surface (deposition surface) is faced downward. Then, in the evaporating mechanism 85 disposed in the processing chamber 70 of the evaporating apparatus 19, the vapor of the evaporating material for the light emitting layer 2 supplied from the evaporating unit 87 is emitted to the surface of the substrate G from the deposition unit 86. Accordingly, as explained in FIG. 1 (2), the light emitting layer 3 (including the hole transport layer, etc.) as the third layer is deposited on the surface of the substrate G.

The substrate G with the light emitting layer 2 formed in the evaporating apparatus 19 is then transferred by the transfer mechanism 20 in the transfer apparatus 11 to the sputtering-evaporating apparatus 13. And, in the sputtering-evaporating apparatus 13, the substrate G and the mask M are held on the lower surface of the stage 42 after aligning them in the alignment mechanism 37. Further, the mask M is transferred into the deposition system 10 via the mask load lock apparatus 16, and then transferred to the sputtering-evaporating apparatus 13 by the transfer mechanism 20 in the transfer apparatus 11.

Thereafter, the transfer mechanism 40 equipped in the sputtering-evaporating apparatus 13 transfers the substrate G and the mask M held on the lower surface of the stage 42 to above the evaporating mechanism 35. Then, by the evaporating mechanism 35, as explained in FIG. 1 (3), the work function adjustment layer 3 as the first layer is vapor deposited on the surface of the substrate G to form a predetermined pattern.

Next, the substrate G and the mask M held on the lower surface of the stage 42 are transferred to above the sputtering mechanism 36. After that, as described in FIG. 1 (4), the cathode layer 4 as the second layer is formed on the surface of the substrate G to form a predetermined pattern by the sputtering mechanism 36.

When the work function adjustment layer 3 and the cathode layer 4 are formed in the sputtering-evaporating apparatus 13, the processing chamber 30 is evacuated through the exhaust port 31. Vapor, which is generated from the evaporating mechanism 35, of alkali metal such as lithium used for forming the work function adjustment layer 3 is evacuated to the outside of the processing chamber 30 through the exhaust port 31 so that the flow of the vapor of the material for the work function adjustment layer 3 toward the sputtering mechanism 36 is prevented. As a result, in the sputtering mechanism 36, the cathode layer 4 can be formed without contamination due to the influence of the adhesive alkali metal such as lithium.

In this way, the substrate G formed with the work function adjustment layer 3 and the cathode layer 4 in the sputtering mechanism 36 is then transferred into the shape forming apparatus 15 by the transfer mechanism 20 of the transfer apparatus 11. Then, in the shape forming apparatus 15, as explained in FIG. 1 (5), the light emitting layer 2 is formed into a predetermined shape corresponding to the cathode layer 4.

The substrate G having the light emitting layer 2 shaped in the shape forming apparatus 15 is again transferred into the sputtering-evaporating apparatus 13 to form a connection portion 4′ relating to the electrode 5, as described in FIG. 1 (6).

After that, the substrate G is transferred into the CVD apparatus 17 by the transfer mechanism 20 of the transfer apparatus 11, and as described in FIG. 1 (7), the OEL device A with the light emitting layer 2 sandwiched by the cathode layer 4 and the anode layer 1 is encapsulated with the sealing film 6, for example, a nitride film. Thus, the organic electroluminescent device A (substrate G) is transferred out of the deposition system 10 via the substrate load lock apparatus 12.

In the aforementioned deposition system 10, since the evaporating mechanism 35 for the work function adjustment layer 3 as the first deposition mechanism is disposed in the process chamber 30 which is different from where the evaporating mechanism 85 as the third deposition mechanism for the light emitting layer 2 is disposed, contamination originating from the adhesive alkali metal, such as lithium, is prevented when forming the light emitting layer 2, and it can be possible to produce the excellent organic EL device A with good light emitting efficiency. In addition, in the evaporating apparatus 19, contamination due to metal mask contact is avoided because a pattern mask is not used when forming the light emitting layer 2.

As the cathode layer 4 is deposited by sputtering, uniform film formation is realized compared to that by an evaporating method. Further, if a facing target sputter (FTS) is adopted as the sputtering mechanism 36, damageless sputtering to the substrate G and the light emitting layer 2 can be realized. Furthermore, as shown in FIG. 1 (7), by encapsulating the substrate G with the sealing film 6 such as a nitride film, it is possible to manufacture the organic EL device A having a superior sealing ability and a good durability.

Hereinbefore, although the favorable embodiment of the present invention has been explained, the present invention is not limited to the embodiment described in the drawings. It would be understood by those skilled in the art that various changes and modifications may be made within the scope of the appended claims. Therefore, they should be construed as being included therein. Though, for example, the present invention has been explained referring to the manufacturing process of the organic electroluminescent device A, the present invention can also be applied to film formations of other electronic devices. In addition, in the manufacturing process of the organic electroluminescent device A, though the work function adjustment layer 3, the cathode layer 4 and the light emitting layer 2 have been explained as the first layer, the second layer and the third layer, respectively, these first layer through third layer are not limited to the work function adjustment layer 3, the cathode layer 4 and the light emitting layer 2. Further, the first deposition mechanism through the third deposition mechanism can be the evaporating mechanism, the sputtering mechanism, the CVD mechanism or other deposition mechanisms. In FIG. 2, one example of the deposition system 10 is shown, but combination of the apparatuses can be changed appropriately.

### INDUSTRIAL APPLICABILITY

The present invention can be applied to the manufacturing field of, for example, an organic electroluminescent device.

What is claimed is:

1. A deposition apparatus for forming a film on a substrate, the apparatus comprising in a processing chamber:
a first deposition mechanism for forming a first layer; and
a second deposition mechanism for forming a second layer,
wherein an exhaust port is provided to evacuate inside of the processing chamber,
the first deposition mechanism is positioned closer to the exhaust port than the second deposition mechanism, and
a substrate transfer mechanism is provided to transfer the substrate to each processing position of the first deposition mechanism and the second deposition mechanism in the processing chamber.

2. (canceled)

3. The deposition apparatus of claim 1, wherein the first deposition mechanism is disposed between the exhaust port and the second deposition mechanism.

4. The deposition apparatus of claim 1, further comprising:
a transfer opening for loading or unloading the substrate into or from the processing chamber,
wherein the first deposition mechanism and the second deposition mechanism are disposed between the exhaust port and the transfer opening.

5. The deposition apparatus of claim 4, further comprising:
an alignment mechanism installed between the second deposition mechanism and the transfer opening to align a mask to a corresponding position of the substrate.

6. The deposition apparatus of claim 5, wherein the substrate transfer mechanism transfers the substrate to each processing position of the first deposition mechanism, the second deposition mechanism and the alignment mechanism in the processing chamber.

7. The deposition apparatus of claim 1, wherein the first deposition mechanism is a film forming mechanism to form a first layer onto the substrate by an evaporation method, and
the second deposition mechanism is a film forming mechanism to form a second layer onto the substrate by a sputtering method.

8. A deposition system for forming a film on a substrate, the system comprising:
a deposition apparatus having a third deposition mechanism for forming a third layer in a processing chamber; and
the deposition apparatus as claimed in claim 1 having the first deposition mechanism and the second deposition mechanism in the processing chamber.

9. The deposition system of claim 8, further comprising:
a transfer mechanism which transfers the substrate between the deposition apparatus having the third deposition mechanism and the deposition apparatus having the first and second deposition mechanisms.

10. The deposition system of claim 8, wherein the third layer is formed by an evaporation method in the third deposition mechanism.

11. A deposition method for forming a film on a substrate with a deposition apparatus which includes in a processing chamber:
a first deposition mechanism for forming a first layer; and
a second deposition mechanism for forming a second layer,
wherein an exhaust port is provided to depressurize inside of the processing chamber,
the first deposition mechanism is disposed closer to the exhaust port than the second deposition mechanism, and
the inside of the processing chamber is evacuated through the exhaust port
the method comprising:
transferring the substrate to a processing position of the first deposition mechanism and then forming a first layer by the first deposition mechanism; and
subsequently, transferring the substrate to a processing position of the second deposition mechanism and then forming a second layer by the second deposition mechanism.

12. (canceled)

13. The deposition method of claim 11, wherein a first layer is deposited on the substrate by an evaporating method by the first deposition mechanism, and
a second layer is formed on the substrate by a sputtering method by the second deposition mechanism.

14. The deposition method of claim 11, further comprising:
forming a third layer by a deposition mechanism in a different processing chamber;
subsequently, forming the first layer by the first deposition mechanism and then forming the second layer by the second deposition mechanism in the processing chamber of the deposition apparatus.

15. (canceled)

16. The deposition method of claim 14, wherein the third layer is formed on the substrate by an evaporating method by the third deposition mechanism, the first layer is formed on the substrate by an evaporating method in the first deposition mechanism and
the second layer is formed on the substrate by a sputtering method in the second deposition mechanism.
